(19) United States
(12) Patent Application Publication
(10) Pub. No.: US 2026/0092740 A1
(43) Pub. Date: Apr. 2, 2026

(54) COATINGS FOR THERMAL PROCESSING APPARATUS AND LAMP HEAT SOURCES

(71) Applicants: Beijing E-Town Semiconductor Technology Co., Ltd., Beijing (CN); Mattson Technology, Inc., Fremont, CA (US)

(72) Inventors: Michael Storek, Dornstadt (DE); Martin L. Albrecht, Neu-Ulm (DE); Rolf Bremensdorfer, Bibertal (DE)

(21) Appl. No.: 19/334,632

(22) Filed: Sep. 19, 2025

Related U.S. Application Data
(60) Provisional application No. 63/700,146, filed on Sep. 27, 2024.

(51) Int. Cl. F27B 17/00; H01L 21/67; H05B 3/00

(52) U.S. Cl. CPC F27B 17/0025; H05B 3/0047; H10P 72/0436

(57) ABSTRACT

A thermal processing apparatus is provided. The thermal processing apparatus includes a processing chamber having a chamber wall. The processing chamber includes a workpiece support. The workpiece support is configured to support a workpiece. The thermal processing apparatus includes one or more lamp heat sources configured to emit electromagnetic radiation to heat the workpiece. The thermal processing apparatus includes an anti-reflection coating in a region between the one or more lamp heat sources and the chamber wall of the processing chamber.

### CROSS-REFERENCE TO PRIORITY APPLICATIONS

The present disclosure claims the benefit of priority of U.S. Provisional Application Ser. No. 63/700,146, filed Sep. 27, 2024, the entirety of which is incorporated by reference herein.

### FIELD

The present disclosure relates generally to thermal processing systems, such as thermal processing systems operable to perform thermal processing of a workpiece, such as a semiconductor workpiece.

### BACKGROUND

A thermal processing chamber as used herein refers to a device that heats workpieces, such as semiconductor workpieces (e.g., semiconductor workpieces). Such devices can include a support plate for supporting one or more workpieces and an energy source for heating the workpieces, such as heating lamps, lasers, or other heat sources. During heat treatment, the workpiece(s) can be heated under controlled conditions according to a processing regime.

Many thermal treatment processes require a workpiece to be heated over a range of temperatures so that various chemical and physical transformations can take place as the workpiece is fabricated into a device(s). During rapid thermal processing, for instance, workpieces can be heated by an array of lamps through the support plate to temperatures from about 300° C. to about 1,200° C. over time durations that are typically less than a few minutes. During these processes, a primary goal can be to reliably and accurately measure a temperature of the workpiece.

### SUMMARY

Aspects and advantages of embodiments of the present disclosure will be set forth in part in the following description, or may be learned from the description, or may be learned through practice of the embodiments.

In an aspect, the present disclosure provides an example thermal processing apparatus. The thermal processing apparatus includes a processing chamber having a chamber wall. The processing chamber includes a workpiece support. The workpiece support is configured to support a workpiece. The thermal processing apparatus includes one or more lamp heat sources configured to emit electromagnetic radiation to heat the workpiece. The thermal processing apparatus includes an anti-reflection coating in a region between the one or more lamp heat sources and the chamber wall of the processing chamber.

In an aspect, the present disclosure provides an example thermal processing apparatus. The thermal processing apparatus includes a processing chamber having a chamber wall. The processing chamber includes a workpiece support. The workpiece support is configured to support a workpiece. The thermal processing apparatus includes one or more lamp heat sources configured to emit electromagnetic radiation to heat the workpiece to a processing temperature. The one or more lamp heat sources includes a reflective coating on the one or more lamp heat sources at a location between a radiation source of the lamp heat source and the chamber wall.

In an aspect, the present disclosure provides an example lamp heat source for a thermal processing chamber. The lamp heat source includes a radiation source. The lamp heat source includes a quartz bulb encasing the radiation source. The lamp heat source includes a reflective coating positioned on the quartz bulb such that a portion of radiation emitted from the radiation source is reflected within the quartz bulb.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIGS. 1A-1B depict example temperature time profiles of a thermal processing system according to example embodiments of the present disclosure;

FIG. 2 depicts an example thermal processing system viewed from the front according to example aspects of the present disclosure;

FIG. 3 depicts a cross-sectional view of a lamp heat source with a coating according to example aspects of the present disclosure;

FIGS. 4A-4B depict a cross-sectional view of lamp heat sources with a coating according to example aspects of the present disclosure;

FIG. 5 depicts a cross-section view of a lamp heat source array as viewed from the front;

FIG. 6 depicts an example thermal processing system viewed from the side according to example aspects of the present disclosure;

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to thermal processing apparatuses, such as rapid thermal processing (RTP) systems, for workpieces, such as semiconductor workpieces (e.g., silicon workpieces). In particular, example aspects of the present disclosure are directed to systems that provide tighter control over a temperature profile during a thermal treatment process, such as an annealing process (e.g., a spike anneal process). An annealing process can be a thermal process which heats workpieces to high temperatures over a desired timescale. Annealing processes can be used, for instance, to activate dopants in a workpiece such as a silicon wafer.

At high temperatures, dopant atoms can diffuse into the workpiece at high rates, with most of the diffusion occurring at peak annealing temperatures required to activate dopants. With increasing performance demands and decreasing device sizes in semiconductor device manufacturing, it can be desirable to tightly control an annealing temperature profile as precisely as possible to subject the workpiece to temperature conditions which serve to activate the dopants while, at the same time, limiting diffusion of the dopants. In this regard, aspects of the present disclosure provide systems and methods for more control over the temperature profile peak width of a workpiece while thermal processing, such as annealing, is being performed on the workpiece.

In some embodiments, directive elements such as, for example, reflectors (e.g., mirrors) can be configured to direct electromagnetic radiation from one or more lamp heating sources towards a workpiece and/or workpiece support plate. The use of directive elements in some thermal processing systems may not provide the level of control needed over the temperature profile of a workpiece undergoing a thermal processing operation. That is, directive elements (e.g., mirrors) may not alter the cooling rate of the workpiece and may not provide sufficient level of control over the ramp rate as compared to aspects of the present disclosure.

Example aspects of the present disclosure are directed towards an anti-reflection coating and/or a reflective coating that, when employed in a thermal processing apparatus, may increase the cooling rate or the ramp rate of a workpiece undergoing thermal processing. By increasing the cooling rate or the ramp rate while thermally processing the workpiece in a thermal processing apparatus, the peak width of a temperature profile over a desired timescale may be reduced compared to the temperature profile of a workpiece undergoing thermal processing in thermal processing systems that do not employ the anti-reflection coating or the reflective coating. According to aspects of the present disclosure, employing the anti-reflection coating to the thermal processing system (i.e., to the chamber wall) may increase the cooling rate of a workpiece by reducing self-heating of the wafer in a thermal processing operation. Further, the ramp rate of the workpiece may be increased by redirecting (e.g., reflecting) electromagnetic radiation that would otherwise not reach the workpiece. The anti-reflection coating may be applied, for instance, in a region between the chamber wall of the thermal processing apparatus, such as a ceiling or a lower surface of the thermal processing apparatus, and one or more lamp heat sources used to heat a workpiece during thermal processing (e.g., annealing) in the thermal processing apparatus.

The reflective coating may increase the ramp rate of the workpiece undergoing thermal processing (e.g., annealing) by reflecting electromagnetic radiation travelling toward the chamber wall or another undesired direction within the thermal processing apparatus and redirecting electromagnetic radiation toward the workpiece. The reflective coating may be applied, for instance, to a portion of one or more lamp heat sources nearest in proximity to the chamber wall having the anti-reflective coating of the thermal processing apparatus.

According to example aspects of the present disclosure, a thermal processing apparatus can include a processing chamber having a chamber wall. The processing chamber may include a workpiece support plate configured to support a workpiece. For example, a workpiece can be a workpiece, such as a substrate, to be processed by the thermal processing apparatus. A workpiece can be or include any suitable workpiece, such as a semiconductor workpiece, such as a silicon workpiece.

A workpiece support plate can be or can include any suitable support structure configured to support a workpiece, such as to support a workpiece in a thermal processing chamber of a thermal processing system. In some embodiments, a workpiece support plate can be configured to support a plurality of workpieces for simultaneous thermal processing by a thermal processing system. In some embodiments, a workpiece support plate can be or include a rotating workpiece support configured to rotate a workpiece while the workpiece is supported by the rotating workpiece support plate. In some embodiments, the workpiece support plate can be transparent to and/or otherwise configured to allow at least some electromagnetic radiation to at least partially pass through the workpiece support plate. For instance, in some embodiments, a material of the workpiece support plate can be selected to allow desired electromagnetic radiation to pass through the workpiece support plate, such as electromagnetic radiation that is emitted by a workpiece and/or emitters and/or measured by sensors in a thermal processing system. In some embodiments, the workpiece support plate can be or include a quartz material.

According to example aspects of the present disclosure, a thermal processing system may include one or more heating sources (e.g., lamp heat sources) configured to heat a workpiece. For example, one or more lamp heat sources may emit electromagnetic radiation (e.g., broadband electromagnetic radiation) to heat a workpiece. In some embodiments, one or more lamp heat sources may be or include, for example, arc lamps, tungsten-halogen lamps, and/or any other suitable lamp heating source, and/or combination thereof.

In some embodiments, an anti-reflection coating may be positioned in a region between the one or more lamp heat sources and the chamber wall of the processing chamber. In some embodiments, the anti-reflection coating may have an average reflectance of less than about 3% for one or more wavelengths in a range of about 0.9 micrometers to about 4.0 micrometers. In some embodiments, the anti-reflection coating may be positioned between the one or more lamp heat sources in a region between the one or more lamp heat sources and the chamber wall of the processing chamber. In some embodiments, the chamber wall is a ceiling. In some embodiments, the chamber wall is a bottom surface.

In some embodiments, the one or more lamp heat sources further include a reflective coating on the one or more lamp heat sources at a location between a radiating portion of the lamp and the anti-reflection coating. In some embodiments, the reflective coating has an average reflectance of greater than about 70% for one or more wavelengths in a range of about 0.9 micrometers to about 3.1 micrometers. In some embodiments, the reflective coating is oriented such that about 120° of a radiation field emitted by the one or more lamp heat sources is reflected by the reflective coating from travelling in a direction toward the chamber wall of the processing chamber. In some embodiments, the reflective coating comprises alumina. In some embodiments, the one or more lamp heat sources includes a quartz bulb encasing a radiation source, wherein the reflective coating is on the quartz bulb.

According to example aspects of the present disclosure, a thermal processing apparatus can include a processing chamber having a chamber wall. The processing chamber may include a workpiece support plate configured to support a workpiece. In some embodiments, the thermal processing apparatus may include one or more lamp heat sources configured to emit electromagnetic radiation to heat the workpiece to a processing temperature, wherein the one or more lamp heat sources includes a reflective coating on the one or more lamp heat sources at a location between a radiation source of the lamp heat source and the chamber wall.

Example aspects of the present disclosure are directed towards a lamp heat source for a thermal processing chamber. The lamp heat source includes a radiation source. The lamp heat source includes a quartz bulb encasing the radiation source. The lamp heat source includes a reflective coating positioned on the quartz bulb such that a portion of radiation emitted from the radiation source is reflected within the quartz bulb.

Systems and methods for thermal processing workpieces according to example aspects of the present disclosure can provide a number of technical effects and benefits related to thermal processing of a workpiece. As one example, apparatuses according to example aspects of the present disclosure can provide finer control over processing parameters, such as the cooling rate or ramp rate of the workpiece during a thermal processing operation. This may lead to higher yield and higher quality workpieces after thermal processing in systems as outlined in the present disclosure.

Variations and modifications can be made to these example embodiments of the present disclosure. As used in the specification, the singular forms “a,” “and,” and “the” include plural referents unless the context clearly dictates otherwise. The use of “first,” “second,” “third,” etc., are used as identifiers and are not necessarily indicative of any ordering, implied or otherwise. Example aspects may be discussed with reference to a “substrate,” “workpiece,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value.

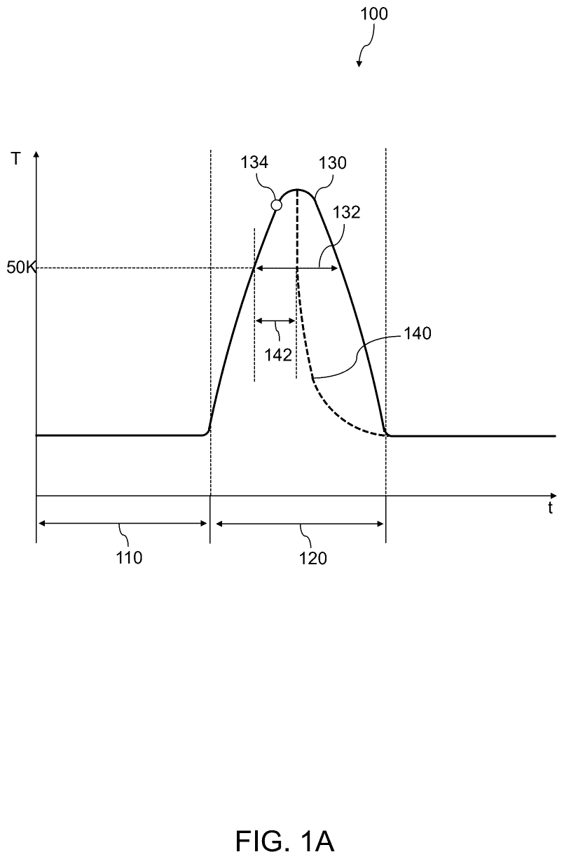

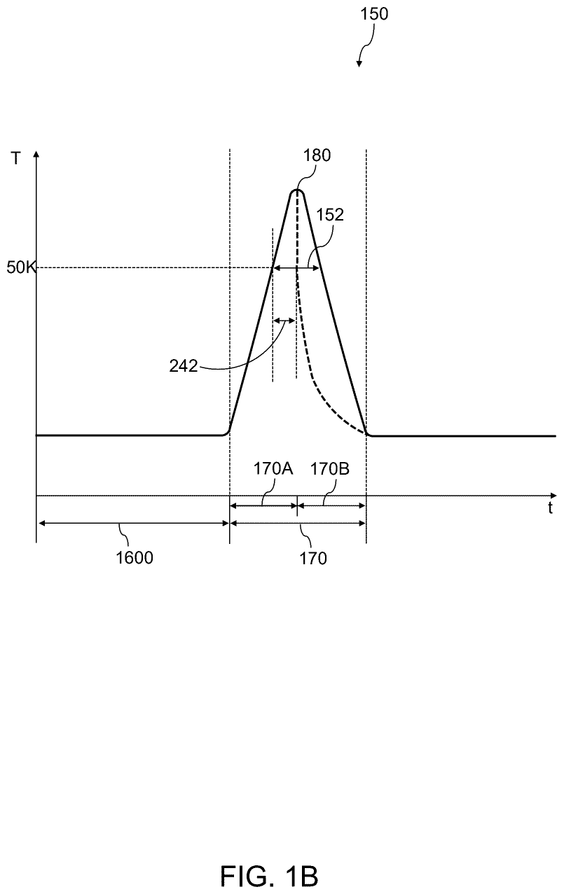

With reference now to the FIGS., example embodiments of the present disclosure will now be discussed in detail. FIG. 1A depicts an example time temperature profile 100 of a thermal processing system according to aspects of the present disclosure. As can be seen in FIG. 1A, subsequent to a first time period 110, an annealing process (e.g., a spike annealing process) occurs during a second time period 120. A heating profile 130 (solid-line curve) can be generated by an annealing process, such as a conventional spike anneal process. In the conventional spike anneal process, one or more heat sources (e.g., lamp heat sources) are controlled to emit electromagnetic radiation to heat a workpiece while monitoring the temperature of the workpiece relative to a temperature setpoint 134. In one aspect, the temperature setpoint 134 is within about 20% of a peak temperature of the heating profile 130 of the workpiece. The heat sources (e.g., lamp heat sources) may be configured to stop emitting electromagnetic radiation once the temperature of the workpiece reaches or surpasses the temperature setpoint 134. The conventional spike anneal can have a defined temperature difference (e.g., 50K) peak width 132 (e.g., T-50 peak width) associated with a temperature ramp portion and/or a cooling portion of the heating profile 130.

FIG. 1B depicts an example time temperature profile 150 of a thermal processing system with an anti-reflection and/or a reflective coating utilized within the thermal processing system according to example embodiments of the present disclosure. Like the time temperature profile 100 of FIG. 1A, the time temperature profile 150 of FIG. 1B includes a first time period 160 and a subsequent second time period 170 in which an annealing process (e.g., a spike anneal process) may be performed. A heating profile 180 (solid-line curve) can be generated by the annealing process, such as a conventional spike anneal process. The conventional spike anneal process that utilizes the anti-reflection coating may lead to a reduction in the second time period 170.

For example, the anti-reflection coating may increase the cooling rate of a workpiece by providing a surface on which excess electromagnetic radiation (e.g., electromagnetic radiation emitted by the workpiece resulting in self-heating of the workpiece) is absorbed, or not reflected to the workpiece during a thermal processing operation. This may reduce the width of the time temperature profile 180 by increasing the slope, or the cooling rate, of the time temperature profile 180 in a cooling region 170B as compared to a thermal process that does not utilize the anti-reflection coating, such as the thermal process of FIG. 1A. In another example, the reflective coating may increase the slope, or the ramp rate, of the time temperature profile 150 in a ramp region 170A as compared to a thermal process that does not utilize the reflective coating, such as the thermal process of FIG. 1A. The reflective coating may reduce the width of the ramp region 170A by reflecting electromagnetic radiation travelling toward the chamber wall or another undesired direction within the thermal processing apparatus and redirecting electromagnetic radiation toward the workpiece.

The anti-reflection coating and/or the reflective coating may alter the overall time temperature profile 150 without adjustments to other thermal processing parameters, such as the setpoint 134 and consequently the peak temperature of the time temperature profile 150. That is to say, a T-50 peak width 152 of a system with the anti-reflection coating and/or the reflective coating may be reduced as compared to the T-50 peak width 132 of a time temperature profile 100 that does not employ the anti-reflection coating or the reflective coating. The reduced peak width 152 (e.g., T-50 peak width) obtained using aspects of the present disclosure may achieve effective annealing cycles at relatively high temperatures while still reducing undesirable processes, such as excessive dopant diffusion.

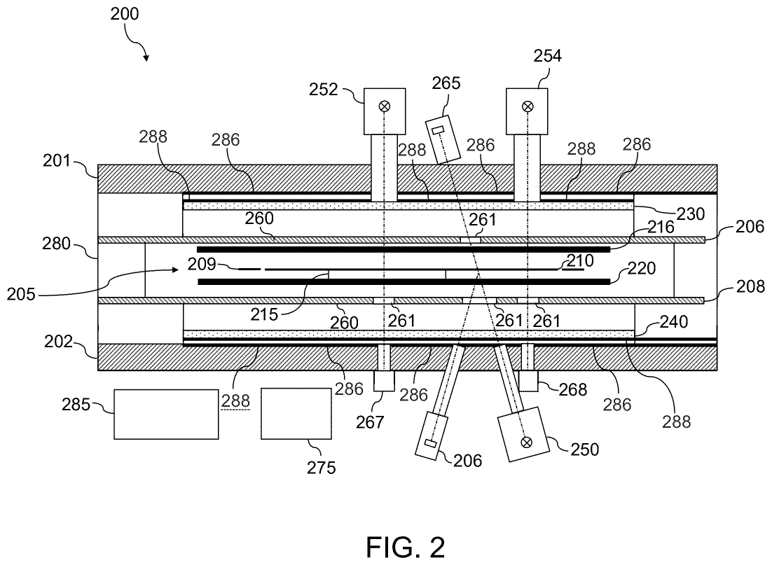

FIG. 2 depicts an example rapid thermal processing (RTP) system 200 as viewed from the front according to example embodiments of the present disclosure. As illustrated, the RTP system 200 includes an RTP chamber 205 including a ceiling 201 and a lower surface 202, windows 206, 208, a workpiece 210, a workpiece support plate 220, one or more heat sources 230, 240 (e.g., lamp heating sources), infrared emitters 250, 252, 254, sensors 265, 266, 267, 268 (e.g., pyrometers, such as dual-head pyrometers), a controller 275, a sidewall/door 280, and a gas flow controller 285.

The workpiece 210 to be processed is supported in the RTP chamber 205 (e.g., a quartz RTP chamber) by the workpiece support plate 220. The workpiece support plate 220 can be a workpiece support operable to support the workpiece 210 during thermal processing. The workpiece 210 can be or include any suitable workpiece, such as a semiconductor workpiece, such as a silicon workpiece. In some embodiments, the workpiece 210 can be or include a lightly doped silicon workpiece. For example, a lightly doped silicon workpiece can be doped such that a resistivity of the silicon workpiece is greater than about 0.1 Ωcm, such as greater than about 1 Ωcm.

The workpiece support plate 220 can be or include any suitable support structure configured to support the workpiece 210, such as to support the workpiece 210 in RTP chamber 205. In some embodiments, the workpiece support plate 220 can be configured to support a plurality of workpieces 210 for simultaneous thermal processing by the RTP system 200. In some embodiments, workpiece support plate 220 can rotate the workpiece 210 before, during, and/or after thermal processing. In some embodiments, the workpiece support plate 220 can be transparent to and/or otherwise configured to allow at least some electromagnetic radiation to at least partially pass through the workpiece support plate 220. For instance, in some embodiments, a material of the workpiece support plate 220 can be selected to allow desired electromagnetic radiation to pass through the workpiece support plate 220, such as electromagnetic radiation that is emitted by the workpiece 210 and/or emitters 250, 252, 254. In some embodiments, the workpiece support plate 220 can be or include a quartz material, such as a hydroxyl free quartz material.

The workpiece support plate 220 can include at least one of a support pin 215 extending from the workpiece support plate 220. In some embodiments, the workpiece support plate 220 can be spaced from a top plate 216. In some embodiments, the support pins 215 and/or the workpiece support plate 220 can transmit heat from the heat sources 240 (e.g., lamp heat sources) and/or absorb heat from the workpiece 210. In some embodiments, the support pins 215, a guard ring 209, and the top plate 216 can be made of quartz.

The guard ring 209 can be used to lessen edge effects of radiation from one or more edges of the workpiece 210. The sidewall/door 280 allows entry of the workpiece 210 and, when closed, allows the RTP chamber 205 to be sealed, such that thermal processing can be performed on the workpiece 210. For example, a process gas can be introduced into the RTP chamber 205. Two banks of heat sources 230, 240 (e.g., a lamp heat source array) may be operable to heat the workpiece 210 in the RTP chamber 205 (e.g., lamps, or other suitable heat sources) are shown on either side of the workpiece 210. The windows 206, 208 can be configured to block at least a portion of radiation emitted by the heat sources 230, 240, as described more particularly below.

The RTP system 200 can include the heat sources 230, 240. In some embodiments, the heat sources 230, 240 can include one or more heating lamps. For example, the heat sources 230, 240 can emit electromagnetic radiation (e.g., broadband electromagnetic radiation) to heat the workpiece 210. In some embodiments, for example, the heat sources 230, 240 can be or include arc lamps, tungsten-halogen lamps, and/or any other suitable heating lamp, and/or combination thereof. In some embodiments, directive elements (not depicted) such as, for example, reflectors (e.g., mirrors) can be configured to direct electromagnetic radiation from heat sources 230, 240 into the RTP chamber 205.

In some examples, the windows 206, 208 can be disposed between the workpiece 210 and the heat sources 230, 240. The windows 206, 208 can be configured to selectively block at least a portion of electromagnetic radiation (e.g., broadband radiation) emitted by the heat sources 230, 240 from entering a portion of the RTP chamber 205. For example, the windows 206, 208 can include one or more opaque regions 260 and/or transparent regions 261. As used herein, “opaque” means generally having a transmittance of less than about 0.4 (40%) for a given wavelength, and “transparent” means generally having a transmittance of greater than about 0.4 (40%) for a given wavelength.

The opaque regions 260 and/or the transparent regions 261 can be positioned such that the opaque regions 260 block stray radiation at some wavelengths from the heat sources 230, 240, and the transparent regions 261 allow, for example, the emitters 250, 252, 254 and/or the sensors 265, 266, 267, 268 to freely interact with radiation in the RTP chamber 205 at the wavelengths blocked by the opaque regions 260. In this way, the windows 206, 208 can effectively shield the RTP chamber 205 from contamination by the heat sources 230, 240 at given wavelengths while still allowing the heat sources 230, 240 to heat the workpiece 210. The opaque regions 260 and the transparent regions 261 can generally be defined as opaque and transparent, respectively, to a particular wavelength; that is, for at least electromagnetic radiation at the particular wavelength, the opaque regions 260 are opaque and the transparent regions 261 are transparent.

The chamber windows 206, 208, including the opaque regions 260 and/or the transparent regions 261, can be formed of any suitable material and/or construction. In some embodiments, the chamber windows 206, 208 can be or include a quartz material. Furthermore, in some embodiments, the opaque regions 260 can be or include hydroxyl (OH) containing quartz, such as hydroxyl doped quartz (e.g., quartz that is doped with hydroxyl), and/or the transparent regions 261 can be or include hydroxyl free quartz (e.g., quartz that is not doped with hydroxyl). Advantages of hydroxyl doped quartz and hydroxyl free quartz can include an ease of manufacturing. For instance, the hydroxyl free quartz regions can be shielded during hydroxyl doping of a monolithic quartz window to produce both hydroxyl doped regions (e.g., opaque regions) and hydroxyl free regions (e.g., transparent regions) in the monolithic window. Additionally, hydroxyl doped quartz can exhibit desirable wavelength blocking properties in accordance with the present disclosure. For instance, hydroxyl doped quartz can block radiation having a wavelength of about 2.7 micrometers, which can correspond to a measurement wavelength at which some sensors (e.g., the sensors 265, 266, 267, 268) in the RTP system 200 operate, while hydroxyl free quartz can be transparent to radiation having a wavelength of about 2.7 micrometers. Thus, the hydroxyl doped quartz regions can shield the sensors (e.g., the sensors 265, 266, 267, 268) from stray radiation in the RTP chamber 205 (e.g., from the heat sources 230, 240), and the hydroxyl free quartz regions can be disposed at least partially within a field of view of the sensors to allow the sensors to obtain measurements within the thermal processing system. Additionally, hydroxyl doped quartz can be partially opaque (e.g., have a transmittance around 0.6, or 60%) to radiation having a wavelength of about 2.3 micrometers, which can at least partially reduce contamination from stray radiation in the RTP system 200 (e.g., from the heat sources 230, 240).

The gas controller 285 can control a gas flow through the RTP system 200, which can include an inert gas that does not react with the workpiece 210 and/or a reactive gas such as oxygen or nitrogen that reacts with the material of the workpiece 210 (e.g. a semiconductor workpiece, etc.) to form a layer on the workpiece 210. In some embodiments, an electrical current can be run through the atmosphere in the RTP system 200 to produce ions that are reactive with or at a surface of the workpiece 210, and to impart extra energy to the surface by bombarding the surface with energetic ions.

The controller 275 controls various components in the RTP chamber to direct thermal processing of the workpiece 210. For example, the controller 275 can be used to control the heat sources 230, 240. Additionally and/or alternatively, the controller 275 can be used to control the gas flow controller 285, the door 280, and/or a temperature measurement system, including, for instance, the emitters 250, 252, 254 and/or the sensors 265, 266, 267, 268. The controller 275 can be configured to measure a temperature of the workpiece 210.

The RTP system 200 may additionally include an anti-reflection coating 286 in a region between the one or more heat sources 230, 240 and the chamber wall of the processing chamber, such as on the ceiling 201 or the lower surface 202 of the RTP system 200. The anti-reflection coating 286 may have an average reflectance of less than about 3% for one or more wavelengths in a range of about 0.9 micrometers to about 4.0 micrometers. The anti-reflection coating 286 may increase the cooling rate of the workpiece 210 during a thermal processing operation performed by the RTP system 200 by providing a surface on which excess electromagnetic radiation from the one or more heat sources 230, 240 or the workpiece 210 is absorbed, or not reflected to the workpiece by the chamber walls (i.e., the ceiling 201 or the lower surface 202).

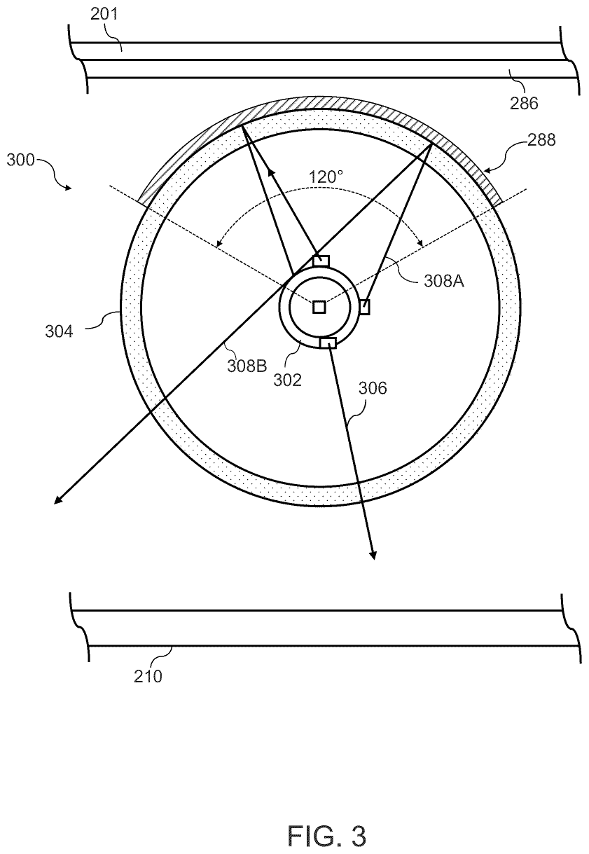

The one or more heat sources 230, 240 of the RTP system 200 may also include a reflective coating 288 on the one or more lamp heat sources 230, 240 at a location between a radiating portion of the lamp heat source 230, 240 and the anti-reflection coating 286. In some embodiments, the reflective coating 288 may be positioned on the one or more heat sources 230, 240 such that 120° of a radiation field emitted by the one or more lamp heat sources 230, 240 is reflected by the reflective coating 288 from travelling in a direction toward the chamber wall (i.e., the ceiling 201 or the lower surface 202) of the processing chamber. In some embodiments, the reflective coating 288 may have an average reflectance of greater than about 70% for one or more wavelengths in a range of about 0.9 micrometers to about 3.1 micrometers. In some embodiments, the reflective coating 288 may be a ceramic material, such as alumina. In some embodiments, the reflective coating 288 may be on a quartz bulb encasing a radiation source within the one or more lamp heat sources 230, 240. The reflective coating 288 and associated components of the one or more heat sources 230, 240 are described further in reference to FIGS. 3-5. The reflective coating 288 may increase the ramp rate of the workpiece 210 during a thermal processing operation performed by the RTP system 200 by reflecting electromagnetic radiation travelling toward the chamber wall (i.e., the ceiling 201 or the lower surface 202) or another undesired direction within the RTP system 200 and redirecting electromagnetic radiation toward the workpiece 210.

FIG. 3 depicts a cross-sectional view of a lamp heat source 300, such as the heat sources 230, 240 of FIG. 2, with a reflective coating 288 according to example aspects of the present disclosure. The lamp heat source 300 includes a radiation source 302 and a protective bulb 304 for the radiation source 302. The radiation source may provide an emission of radiation 306 in a first direction toward the workpiece 210, or an emission of radiation 308A in a first direction away from the workpiece 210. The reflective coating 288 may be positioned to reflect the emission of radiation 308A travelling in a first direction away from the workpiece 210 to a second direction 308B travelling toward the workpiece 210.

In some embodiments, the reflective coating 288 has an average reflectance of greater than about 70% for one or more wavelengths in range of about 0.9 micrometers to about 3.1 micrometers. In some embodiments, the reflective coating may be a ceramic material, such as alumina. In some embodiments, the reflective coating 288 is positioned on the lamp heat source 300, such as on the protective bulb 304 (e.g., a quartz protective bulb 304), such that 120° of a radiation field emitted by the radiation source 302 is reflected by the reflective coating 288 from travelling in a direction toward a chamber wall, or toward the anti-reflection coating 286. As pictured in FIG. 3, the chamber wall may be the ceiling 201 of the RTP system. In some embodiments, the lamp heat source 300 may be positioned below a workpiece 210, and the reflective coating 288 may be applied to a portion of the protective bulb 304 nearest to a lower surface (e.g., the lower surface 202 of FIG. 2) of the RTP system. In some embodiments, the protective bulb 304 may be made of a ceramic material such as quartz.

FIG. 3 depicts a simplified view of the lamp heat source 300 for purposes of illustration and discussion, it will be understood by one skilled in the art, using the disclosures provided herein, that other components (e.g., the windows 206, 208, the top plate 216 or the workpiece support plate 220, etc.) of the RTP system may be present in conjunction with the lamp heat source 300.

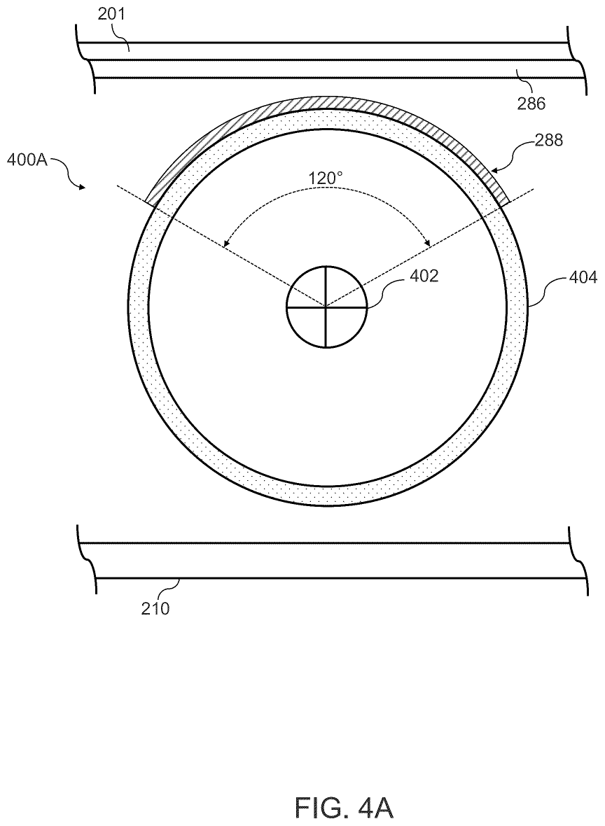

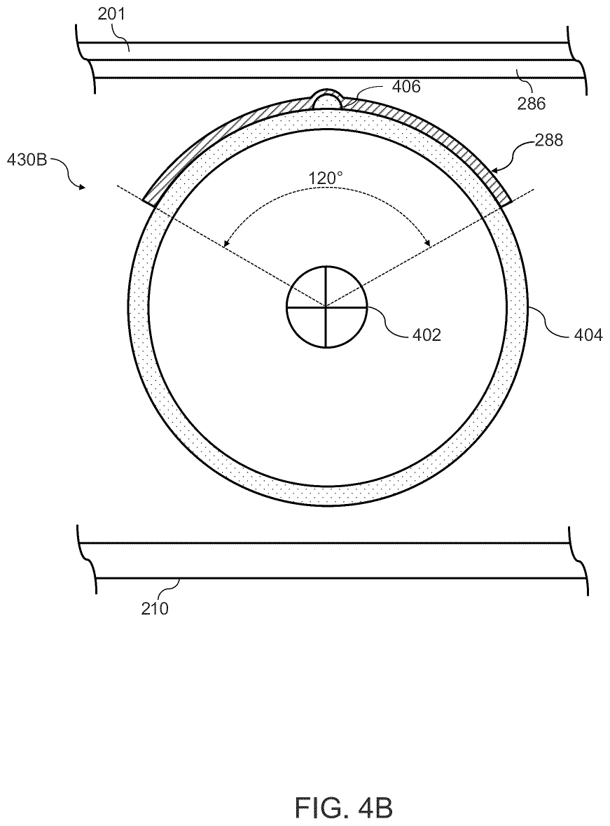

FIG. 4A depicts a cross-sectional view of a lamp heat source 400A, such as the heat sources 230, 240 of FIG. 2, with a reflective coating 288 according to example aspects of the present disclosure. Like the lamp heat source 300 of FIG. 3, the lamp heat source 400A includes a radiation source 402 and a protective bulb 404 for the radiation source 402.

In some embodiments, the reflective coating 288 has an average reflectance of greater than about 70% for one or more wavelengths in range of about 0.9 micrometers to about 3.1 micrometers. In some embodiments, the reflective coating may be a ceramic material, such as alumina. In some embodiments, the reflective coating 288 is positioned on the lamp heat source 400A, such as on the protective bulb 404 (e.g., a quartz protective bulb 404), such that 120° of a radiation field emitted by the radiation source 402 is reflected by the reflective coating 288 from travelling in a direction toward a chamber wall. As pictured in FIG. 4A, the chamber wall may be the ceiling 201 of the RTP system. In some embodiments, the lamp heat source 400A may be positioned below a workpiece 210, and the reflective coating 288 may be applied to a portion of the protective bulb 404 nearest to a lower surface (e.g., the lower surface 202 of FIG. 2) of the RTP system. In some embodiments, the protective bulb 404 may be made of a ceramic material such as quartz.

FIG. 4A depicts a simplified view of the lamp heat source 400A for purposes of illustration and discussion, it will be understood by one skilled in the art, using the disclosures provided herein, that other components (e.g., the windows 206, 208, the top plate 216 or the workpiece support plate 220, etc.) of the RTP system may be present in conjunction with the lamp heat source 300.

FIG. 4B depicts a cross-sectional view of a lamp heat source 400B, such as the heat sources 230, 240 of FIG. 2, with a reflective coating 288 according to example aspects of the present disclosure. Like the lamp heat source 300 of FIG. 3, and the lamp heat source 400 of FIG. 4A, the lamp heat source 400B includes a radiation source 402 and a protective bulb 404 for the radiation source 402. The lamp heat source 400B may also include a gas fill port 406. The gas fill port 406 may indicate the protective bulb 404 of the lamp heat source 400B is filled with an inert gas, which may increase the lifespan or operating temperature of the lamp heat source 400B.

In some embodiments, the reflective coating 288 has an average reflectance of greater than about 70% for one or more wavelengths in range of about 0.9 micrometers to about 3.1 micrometers. In some embodiments, the reflective coating may be a ceramic material, such as alumina. In some embodiments, the reflective coating 288 is positioned on the lamp heat source 400B, such as on the protective bulb 404 (e.g., a quartz protective bulb 404), such that 120° of a radiation field emitted by the radiation source 402 is reflected by the reflective coating 288 from travelling in a direction toward a chamber wall. As pictured in FIG. 4B, the chamber wall may be the ceiling 201 of the RTP system. In some embodiments, the lamp heat source 400A may be positioned below a workpiece 210, and the reflective coating 288 may be applied to a portion of the protective bulb 404 nearest to a lower surface (e.g., the lower surface 202 of FIG. 2) of the RTP system. In some embodiments, the protective bulb 404 may be made of a ceramic material such as quartz.

FIG. 4 depicts a simplified view of the lamp heat source 400B for purposes of illustration and discussion, it will be understood by one skilled in the art, using the disclosures provided herein, that other components (e.g., the windows 206, 208, the top plate 216 or the workpiece support plate 220, etc.) of the RTP system may be present in conjunction with the lamp heat source 300.

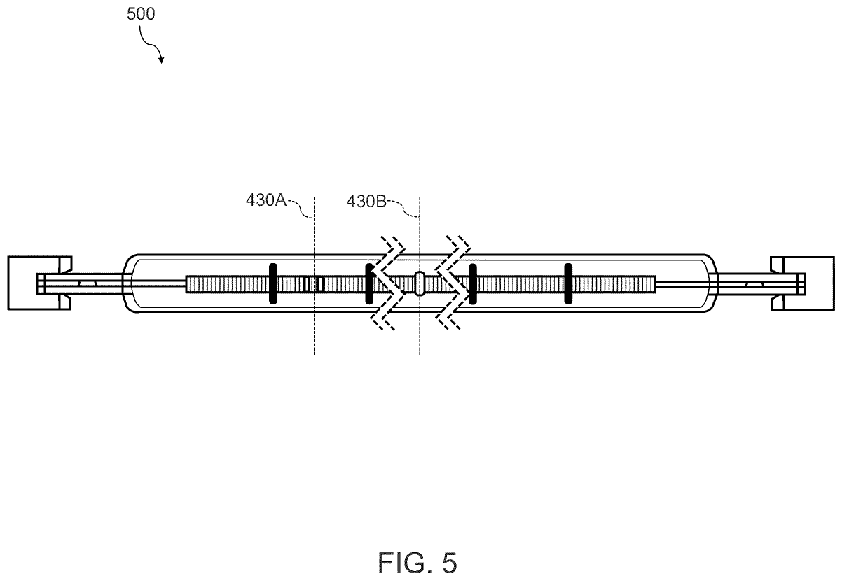

FIG. 5 depicts an overview of the lamp heat source 430A and the lamp heat source 430B in an array of lamp heat sources 500. The array of lamp heat sources 500 may include the lamp heat source 400A on an outer periphery of the array of lamp heat sources 500. The array of lamp heat sources 500 may include the lamp heat source 400B on a central portion of the array of lamp heat sources 500. The arrangement of lamp heat sources 400A, 400B in the array of lamp heat sources 500 may allow the lamp heat sources 400B to have increased lifespan or operating temperature of the lamp heat source 400B in the array of lamp heat sources 500.

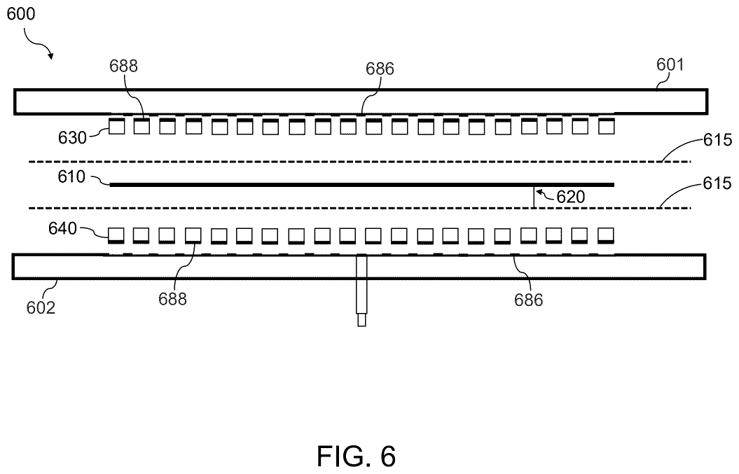

FIG. 6 depicts a simplified view of an example rapid thermal processing (RTP) system 600 as viewed from the side according to example embodiments of the present disclosure. As illustrated, the RTP system 600 includes a ceiling 601 and a lower surface 602, windows 615, a workpiece 610, a workpiece support plate 620, and one or more heat sources 630, 640 (e.g., lamp heating sources).

The RTP system 600 can include the heat sources 630, 640. In some embodiments, the heat sources 630, 640 can include one or more heating lamps. For example, the heat sources 630, 640 can emit electromagnetic radiation (e.g., broadband electromagnetic radiation) to heat the workpiece 610. In some embodiments, for example, the heat sources 630, 640 can be or include arc lamps, tungsten-halogen lamps, and/or any other suitable heating lamp, and/or combination thereof. In some embodiments, directive elements (not depicted) such as, for example, reflectors (e.g., mirrors) can be configured to direct electromagnetic radiation from heat sources 630, 640 into the RTP chamber 605.

The RTP system 600 may additionally include an anti-reflection coating 686, as depicted in FIG. 6, in a region between the one or more lamp heat sources 630, 640 and the chamber wall (e.g., the ceiling 601 or the lower surface 602) of the RTP system 600. The anti-reflection coating 686 may have an average reflectance of less than about 3% for one or more wavelengths in a range of about 0.9 micrometers to about 4.0 micrometers. The anti-reflection coating 686 may increase the cooling rate of the workpiece 610 during a thermal processing operation performed by the RTP system 600 by providing a surface on which excess electromagnetic radiation from the one or more heat sources 630, 640 or the workpiece 610 is absorbed, or not reflected to the workpiece by the chamber walls (i.e., the ceiling 601 or the lower surface 602).

The one or more heat sources 630, 640 of the RTP system 600 may also include a reflective coating 688 on the one or more lamp heat sources 630, 640 at a location between a radiating portion of the lamp heat source 630, 640 and the anti-reflection coating 686. In some embodiments, the reflective coating 688 may be positioned on the one or more heat sources 630, 640 such that 120° of a radiation field emitted by the one or more lamp heat sources 630, 640 is reflected by the reflective coating 688 from travelling in a direction toward the chamber wall (i.e., the ceiling 601 or the lower surface 602) of the processing chamber. In some embodiments, the reflective coating 688 may have an average reflectance of greater than about 70% for one or more wavelengths in a range of about 0.9 micrometers to about 3.1 micrometers. In some embodiments, the reflective coating 688 may be a ceramic material, such as alumina. In some embodiments, the reflective coating 688 may be on a quartz bulb encasing a radiation source within the one or more lamp heat sources 630, 640. The reflective coating 688 and associated components of the one or more heat sources 630, 640 are described further in reference to FIGS. 3-5. The reflective coating 688 may increase the ramp rate of the workpiece 610 during a thermal processing operation performed by the RTP system 600 by reflecting electromagnetic radiation travelling toward the chamber wall (i.e., the ceiling 601 or the lower surface 602) or another undesired direction within the RTP system 600 and redirecting electromagnetic radiation toward the workpiece 610.

In an aspect, the present disclosure provides an example thermal processing apparatus. The thermal processing apparatus includes a processing chamber having a chamber wall. The processing chamber includes a workpiece support. The workpiece support is configured to support a workpiece. The thermal processing apparatus includes one or more lamp heat sources configured to emit electromagnetic radiation to heat the workpiece. The thermal processing apparatus includes an anti-reflection coating in a region between the one or more lamp heat sources and the chamber wall of the processing chamber.

In some examples, the anti-reflection coating has an average reflectance of less than about 3% for one or more wavelengths in a range of about 0.9 micrometers to about 4.0 micrometers.

In some examples, the anti-reflection coating is between the one or more lamp heat sources in a region between the one or more lamp heat sources and the chamber wall of the processing chamber.

In some examples, the chamber wall is a ceiling.

In some examples, the chamber wall is a bottom surface.

In some examples, the one or more lamp heat sources further comprise a reflective coating on the one or more lamp heat sources at a location between a radiating portion of the lamp and the anti-reflection coating.

In some examples, the reflective coating has an average reflectance of greater than about 70% for one or more wavelengths in a range of about 0.9 micrometers to about 3.1 micrometers.

In some examples, the reflective coating is oriented such that about 120° of a radiation field emitted by the one or more lamp heat sources is reflected by the reflective coating from travelling in a direction toward the chamber wall of the processing chamber.

In some examples, the reflective coating comprises alumina.

In some examples, the one or more lamp heat sources includes a quartz bulb encasing a radiation source. In some examples, the reflective coating is on the quartz bulb.

In an aspect, the present disclosure provides an example thermal processing apparatus. The thermal processing apparatus includes a processing chamber having a chamber wall. The processing chamber includes a workpiece support. The workpiece support is configured to support a workpiece. The thermal processing apparatus includes one or more lamp heat sources configured to emit electromagnetic radiation to heat the workpiece to a processing temperature. The one or more lamp heat sources includes a reflective coating on the one or more lamp heat sources at a location between a radiation source of the lamp heat source and the chamber wall.

In some examples, the reflective coating has an average reflectance of greater than about 70% for one or more wavelengths in range of about 0.9 micrometers to about 3.1 micrometers.

In some examples, the reflective coating is oriented such that about 120° of a radiation field emitted by the one or more lamp heat sources is reflected by the reflective coating from travelling in a direction toward the chamber wall of the processing chamber.

In some examples, the chamber wall is a ceiling.

In some examples, the chamber wall is a bottom surface.

In some examples, the reflective coating comprises alumina.

In some examples an anti-reflection coating is in a region between the one or more lamp heat sources and the chamber wall of the processing chamber.

In some examples, the anti-reflection coating has an average reflectance of less than about 3% for one or more wavelengths in a range of about 0.9 micrometers to about 4.0 micrometers.

In some examples, the anti-reflection coating is in a region between the one or more lamp heat sources and the chamber wall of the processing chamber.

In an aspect, the present disclosure provides an example lamp heat source for a thermal processing chamber. The lamp heat source includes a radiation source. The lamp heat source includes a quartz bulb encasing the radiation source. The lamp heat source includes a reflective coating positioned on the quartz bulb such that a portion of radiation emitted from the radiation source is reflected within the quartz bulb.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A thermal processing apparatus, comprising:
a processing chamber having a chamber wall, wherein the processing chamber includes a workpiece support, the workpiece support configured to support a workpiece;
one or more lamp heat sources configured to emit electromagnetic radiation to heat the workpiece; and
an anti-reflection coating in a region between the one or more lamp heat sources and the chamber wall of the processing chamber.

2. The thermal processing apparatus of claim 1, wherein the anti-reflection coating has an average reflectance of less than about 3% for one or more wavelengths in a range of about 0.9 micrometers to about 4.0 micrometers.

3. The thermal processing apparatus of claim 1, wherein the anti-reflection coating is between the one or more lamp heat sources in a region between the one or more lamp heat sources and the chamber wall of the processing chamber.

4. The thermal processing apparatus of claim 1, wherein the chamber wall is a ceiling.

5. The thermal processing apparatus of claim 1, wherein the chamber wall is a bottom surface.

6. The thermal processing apparatus of claim 1, wherein the one or more lamp heat sources further comprise a reflective coating on the one or more lamp heat sources at a location between a radiating portion of the lamp and the anti-reflection coating.

7. The thermal processing apparatus of claim 6, wherein the reflective coating has an average reflectance of greater than about 70% for one or more wavelengths in a range of about 0.9 micrometers to about 3.1 micrometers.

8. The thermal processing apparatus of claim 6, wherein the reflective coating is oriented such that about 120° of a radiation field emitted by the one or more lamp heat sources is reflected by the reflective coating from travelling in a direction toward the chamber wall of the processing chamber.

9. The thermal processing apparatus of claim 6, wherein the reflective coating comprises alumina.

10. The thermal processing apparatus of claim 6, wherein the one or more lamp heat sources includes a quartz bulb encasing a radiation source, wherein the reflective coating is on the quartz bulb.

11. A thermal processing apparatus, comprising:
a processing chamber having a chamber wall, wherein the processing chamber includes a workpiece support, the workpiece support configured to support a workpiece; and
one or more lamp heat sources configured to emit electromagnetic radiation to heat the workpiece to a processing temperature, wherein the one or more lamp heat sources includes a reflective coating on the one or more lamp heat sources at a location between a radiation source of the lamp heat source and the chamber wall.

12. The thermal processing apparatus of claim 11, wherein the reflective coating has an average reflectance of greater than about 70% for one or more wavelengths in range of about 0.9 micrometers to about 3.1 micrometers.

13. The thermal processing apparatus of claim 11, wherein the reflective coating is oriented such that about 120° of a radiation field emitted by the one or more lamp heat sources is reflected by the reflective coating from travelling in a direction toward the chamber wall of the processing chamber.

14. The thermal processing apparatus of claim 11, wherein the chamber wall is a ceiling.

15. The thermal processing apparatus of claim 11, wherein the chamber wall is a bottom surface.

16. The thermal processing apparatus of claim 11, wherein the reflective coating comprises alumina.

17. The thermal processing apparatus of claim 11, wherein an anti-reflection coating is in a region between the one or more lamp heat sources and the chamber wall of the processing chamber.

18. The thermal processing apparatus of claim 17, wherein the anti-reflection coating has an average reflectance of less than about 3% for one or more wavelengths in a range of about 0.9 micrometers to about 4.0 micrometers.

19. The thermal processing apparatus of claim 17, wherein the anti-reflection coating is in a region between the one or more lamp heat sources and the chamber wall of the processing chamber.

20. A lamp heat source for a thermal processing chamber, comprising:
a radiation source;
a quartz bulb encasing the radiation source; and
a reflective coating positioned on the quartz bulb such that a portion of radiation emitted from the radiation source is reflected within the quartz bulb.
